(19) United States
(12) Patent Application Publication
(10) Pub. No.: US 2025/0118529 A1
(43) Pub. Date: Apr. 10, 2025

(54) MULTI-BEAM WRITING METHOD AND MULTI-BEAM WRITING APPARATUS

(71) Applicant: NuFlare Technology, Inc., Yokohama-shi (JP)

(72) Inventors: Haruyuki NOMURA, Yokohama-shi (JP); Takahito NAKAYAMA, Chigasaki-shi (JP)

(73) Assignee: NuFlare Technology, Inc., Yokohama-shi (JP)

(21) Appl. No.: 18/890,971

(22) Filed: Sep. 20, 2024

(30) Foreign Application Priority Data
Oct. 5, 2023 (JP) 2023-173682

(51) Int. Cl. H01J 37/317; H01J 37/304

(52) U.S. Cl. CPC H01J 37/3177; H01J 37/3045

(57) ABSTRACT

In one embodiment, a multi-beam writing method is for dividing a writing region of a substrate into multiple stripe regions, and writing each stripe region with a predetermined within-stripe multiplicity of N, where N is an integer greater than 1. The multi-beam writing method includes generating M different types of segments that define a shot order for multiple pixels belonging to each of multiple cells into which the stripe region is divided, the M being an integer greater than 1, irradiating the multiple pixels in the cell with a first individual beam using (m−1)th segment, where m is an integer such that 2≤m≤M, then irradiating the multiple pixels in the cell with a second individual beam different from the first individual beam using mth segment, and writing all pixels in each cell with the multiplicity of N by repeating irradiation sequentially using the M types of segments.

### CROSS REFERENCE TO RELATED APPLICATION

This application is based upon and claims benefit of priority from the Japanese Patent Application No. 2023-173682, filed on Oct. 5, 2023, the entire contents of which are incorporated herein by reference.

### FIELD

The present invention relates to a multi-beam writing method and a multi-beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern formed as a light shielding film or a reflective film on quartz is transferred to a wafer in a reduced manner by using a reduced-projection exposure apparatus. To produce such high-precision original patterns, so-called electron beam lithography technology is used, in which patterns are formed by exposing resist with an electron beam writing apparatus.

A writing apparatus that uses a multi-beam can emit more beams at one time than a writing apparatus that performs writing by a single electron beam, thus the throughput can be significantly improved. As a form of multi-beam writing apparatus, a multi-beam writing apparatus using a blanking aperture array forms a multi-beam including a plurality of beamlets (individual beams) by passing an electron beam emitted from an electron source through a shaping aperture array having a plurality of openings. The multi-beam passes through corresponding blankers mentioned below of the blanking aperture array. The blanking aperture array has electrode pairs (blankers) for individually deflecting beams, and includes an opening for beam passage between each electrode pair. Blanking deflection is performed on the passing electron beam by controlling the electrode pair at the same electrical potential or at different electrical potentials. An individual beam deflected by a blanker is blocked, and an individual beam not deflected is emitted onto a substrate.

In a writing process, for example, the writing region of a substrate is virtually divided into a plurality of rectangular stripe regions with a predetermined width in the y direction, a beam array is adjusted to be positioned at the left end of the first stripe region, and writing is performed in +X direction. After completion of writing of the first stripe region, the beam array is adjusted to be positioned at the right end of the second stripe region, and writing is performed in −X direction.

As a high-precision writing system, a multiple-writing system is known in which multiple-writing is performed with a necessary irradiation amount divided into multiple processes of writing (exposures). In multiple-writing using a multi-beam, the error in position and current amount for each beam is averaged to reduce the error in dimensions and position of a writing pattern. As a multiple-writing system, stripe multiple-writing in which stripes are shifted and overlaid, and within-stripe multiple-writing in which multiple exposure is performed within one stripe are known.

In the within-stripe multiple-writing, for example, a stripe region on the substrate is divided into a plurality of beam pitch cells by an inter-beam pitch size of multi-beam. Each beam pitch cell is further divided into a plurality of pixels. The beam is shot to all pixels in a shot order assigned to the pixels, then the beam is further shot to all pixels again in the same shot order. In this example, the same area is shot twice, thus the multiple-writing has a multiplicity of two.

For example, a case is discussed where each beam pitch cell consists of 10 pixels×10 pixels=100 pixels, the stage for placing a substrate is moved continuously, and while stage tracking is performed, 10 pixels in the first row of the beam pitch cell are exposed sequentially. When shot is performed 10 times to expose 10 pixels, an operation (tracking reset) of returning the beam position to the tracking start position is performed. The exposure of 10 pixels and the tracking reset are repeatedly performed to expose 100 pixels one time each, thus the first of multiple exposures is completed. The shot order of 100 pixels is as illustrated in FIG. 22. 100 pixels in the beam pitch cell are exposed again in the same shot order by the same procedure, and the second of multiple exposures is completed.

However, when a systematic error according to the shot order occurs, a problem arises in that an averaging effect by the multiple-writing is not obtained because each beam pitch cell is shot in the same shot order in the first and second of multiple exposures. For example, when due to the tracking reset operation, a charge is generated in the column to cause a positional deviation of the beam, and the positional deviation decays during exposure operations for 10 pixels during tracking, a distribution of the deviation of the shot position as in FIG. 10 is generated. In the example above, each beam pitch cell is shot in the same shot order in the first and second of multiple exposures, thus an averaging effect by the multiple-writing is not obtained, and as illustrated in FIG. 11, a systematic error occurs in the shot position of each pixel, which causes an error in the position and the linewidth of a writing pattern.

A technique is known which makes a systematic error unlikely to occur by positionally changing the shot order within each beam pitch cell. For example, the distribution of error in shot position can be spatially dispersed when a shot order is used which allows the exposure positions in the beam pitch cell during tracking to be dispersed without deviating in neither the X direction nor the Y direction as illustrated in FIG. 23. The shot order can be generated by a random number generator. However, even if such a technique is used, each beam pitch cell to be exposed simultaneously by a multi-beam is shot in the same shot order, thus it has been difficult to sufficiently reduce the systematic error according to the shot order.

### BRIEF DESCRIPTION OF THE DRAWINGS

FIG. 1 is a schematic view of a multi-charged particle beam writing apparatus according to an embodiment of the present invention.

FIG. 2 is a plan view of a shaping aperture member.

FIG. 3 is a view for explaining an example of a writing operation.

FIG. 4 is a view illustrating an example of an irradiation region of a multi-beam and writing target pixels.

FIG. 5 is a view for explaining an example of a writing operation.

FIG. 6 is a view for explaining an example of a writing operation.

FIGS. 7A to 7C are explanatory views of within-stripe multiple-writing.

FIGS. 8A to 8C are explanatory views of within-stripe multiple-writing.

FIGS. 9A to 9C are explanatory views of within-stripe multiple-writing.

FIG. 10 is a view illustrating a deviation of shot position.

FIG. 11 is a view illustrating an example of a systematic error according to shot order.

FIG. 12 is a view illustrating an example of a beam array.

FIGS. 13A to 13D are explanatory views of a within-stripe multiple-writing method according to the embodiment.

FIGS. 14A to 14D are explanatory views of a within-stripe multiple-writing method according to the embodiment.

FIG. 15 is a view illustrating an example of segments in which a shot order and shot positions are defined.

FIGS. 16A to 16D are views for explaining a shot order within each pitch cell.

FIG. 17 is a view illustrating an example of a beam array.

FIG. 18 is a view illustrating an example of segments in which a shot order and shot positions are defined.

FIGS. 19A to 19C are explanatory views of a within-stripe multiple-writing method according to the embodiment.

FIGS. 20A to 20C are explanatory views of a within-stripe multiple-writing method according to the embodiment.

FIG. 21 is a view illustrating an example of segments in which a shot order and shot positions are defined.

FIG. 22 is a view for explaining a shot order within a pitch cell.

FIG. 23 is a view for explaining a shot order within a pitch cell.

### DETAILED DESCRIPTION

In one embodiment, a multi-beam writing method is for dividing a writing region of a substrate on a stage to be irradiated with a beam array of a multi-beam into multiple stripe regions with a predetermined width in a direction perpendicular to a proceed direction of writing, dividing each of the stripe regions into multiple pixels each of which is an irradiation unit region for each of individual beams included in the multi-beam, and writing each stripe region with a predetermined within-stripe multiplicity of N, where N is an integer greater than 1. The multi-beam writing method includes generating M different types of segments that define a shot order for multiple pixels belonging to each of multiple cells into which the stripe region is divided, the M being an integer greater than 1, irradiating the multiple pixels in the cell with a first individual beam using (m−1)th segment, where m is an integer such that 2≤m≤M, while the multi-beam is being deflected, then irradiating the multiple pixels in the cell with a second individual beam different from the first individual beam using mth segment, and writing all pixels in each cell with the multiplicity of N by repeating irradiation sequentially using the M types of segments.

Hereinafter, an embodiment of the present invention will be described based on the drawings. In the present embodiment, a configuration using an electron beam as an example of a beam will be described. The beam is not limited to the electron beam, but may be other charged particle beam such as an ion beam.

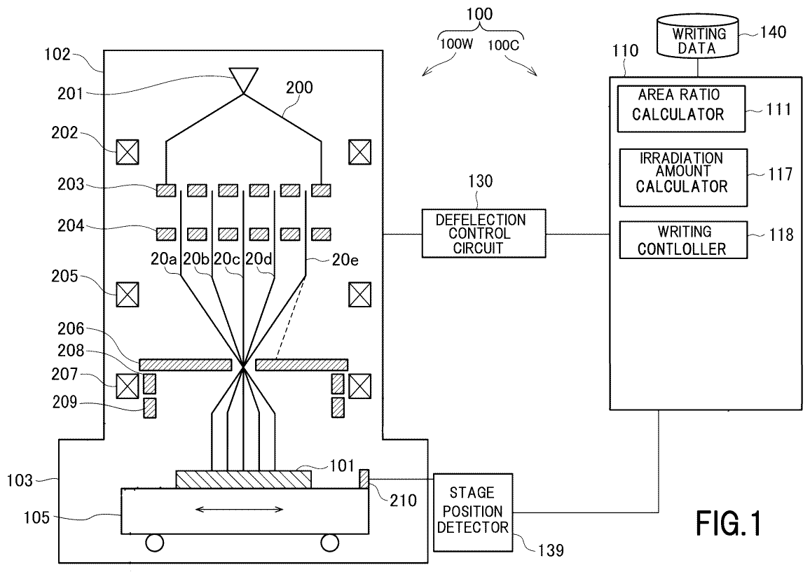

FIG. 1 is a schematic view of a writing apparatus according to an embodiment. As illustrated in FIG. 1, a writing apparatus 100 includes a writer 100W and a controller 100C. The writing apparatus 100 is an example of a multi-charged particle beam writing apparatus. The writer 100W includes an electron optical column 102 and a writing chamber 103. In the electron optical column 102, an electron source 201, an illumination lens 202, a shaping aperture member 203, a blanking aperture array substrate 204, a reduction lens 205, a limiting aperture member 206, an objective lens 207, and deflectors 208, 209 which constitute a multi-beam generation mechanism are disposed. As described later, the deflector 208 is used for stage tracking deflection, and the deflector 209 is used for positioning of multi-beam with respect to pixels. Note that one deflector having both functions of the deflector 209 and the deflector 208 may be installed, and both stage tracking deflection and positioning of multi-beam with respect to pixels may be performed by the one deflector.

In the writing chamber 103, an XY stage 105 is disposed. A substrate 101 as a writing target is disposed on the XY stage 105. The substrate 101 is e.g., a mask blank or a semiconductor substrate (silicon wafer).

A mirror 210 for position measurement is disposed on the XY stage 105.

The controller 100C includes a control computer 110, a deflection control circuit 130, a stage position detector 139, and a storage 140. The storage 140 receives input of writing data from the outside, and stores it. In addition, the storage 140 stores information on segments described later. The writing data normally defines information on a plurality of figure patterns to be written. Specifically, for each figure pattern, the figure code, the coordinates, and the size are defined.

The control computer 110 includes an area ratio calculator 111, an irradiation amount calculator 117, and a writing controller 118. Each component of the control computer 110 may be comprised of hardware such as an electric circuit, or software such as programs that execute these functions. Alternatively, the component may be comprised of a combination of hardware and software.

The stage position detector 139 emits a laser, receives reflected light from the mirror 210, and detects the position of the XY stage 105 by a laser interference method.

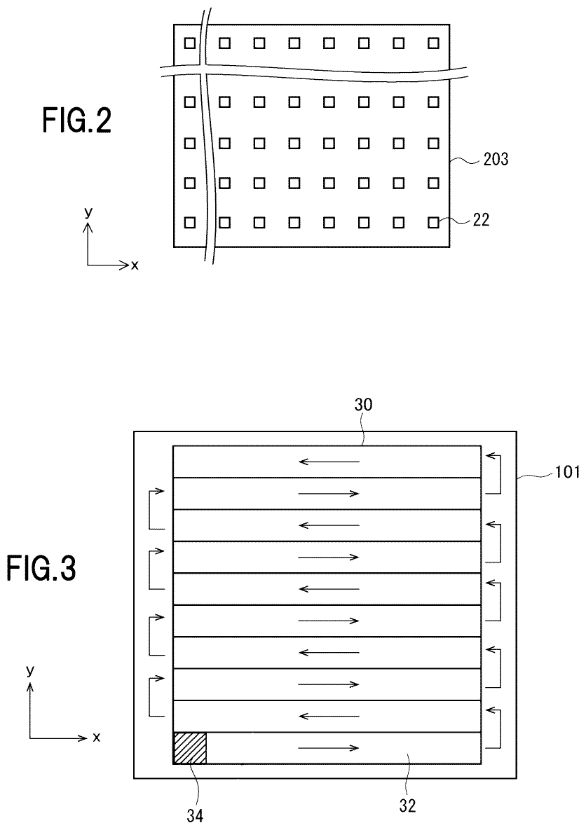

FIG. 2 is a conceptual diagram illustrating the configuration of the shaping aperture member 203. As illustrated in FIG. 2, in the shaping aperture member 203, openings 22 are formed in m vertical (y direction) rows and n horizontal (x direction) columns (m, n≥2) with a predetermined arrangement pitch. The openings 22 are formed in rectangular shapes having the same dimensions. The openings 22 may have a circular shape with the same outer diameter. Part of an electron beam 200 passes through each of these multiple openings 22, thereby forming multi-beams 20a to 20e.

In the blanking aperture array substrate 204, passage holes are formed corresponding to the arrangement positions of the openings 22 of the shaping aperture member 203. Each passage hole is provided with a set (blanker) of two electrodes as a pair. The electron beam passing through each passage hole is independently controlled beam by beam at a beam-on or beam-off state by a voltage applied to the blanker. In beam-on state, the opposed electrodes of the blanker are controlled at the same potential, and the blanker does not deflect the beam. In beam-off state, the opposed electrodes of the blanker are controlled at different potentials, and the blanker deflects the beam. In this manner, multiple blankers perform blanking deflection on corresponding beams in the multi-beams which have passed through the multiple openings 22 of the shaping aperture member 203.

The electron beam 200 discharged from the electron source 201 (discharger) illuminates the shaping aperture member 203 in its entirety substantially perpendicularly by the illumination lens 202. The electron beam 200 illuminates a region including all openings 22. The electron beam 200 passes through multiple openings 22 of the shaping aperture member 203, thereby forming e.g., rectangular multiple electron beams (multi-beams) 20a to 20e.

The multi-beams 20a to 20e pass through corresponding blankers of the blanking aperture array substrate 204. The blankers each individually deflect a passing electron beam. The multi-beams 20a to 20e which have passed through the blanking aperture array substrate 204 are reduced by the reduction lens 205, and in ON state of all beams, ideally pass through the same point on the limiting aperture member 206. In order to position the point within the opening in the center of the limiting aperture member 206, the trajectory of the beam is adjusted by an alignment coil which is not illustrated.

Any beam controlled at beam-off state is deflected by a blanker of the blanking aperture array substrate 204, and the beam trajectory passes through outside the opening of the limiting aperture member 206, thus is blocked by the limiting aperture member 206. In contrast, any beam controlled at beam-on state is not deflected by a blanker, thus passes through the opening of the limiting aperture member 206. In this manner, ON/OFF of the beam is controlled by the blanking control of the blanking aperture array substrate 204.

The limiting aperture member 206 blocks the beams that are deflected by multiple blankers to achieve beam-off state. The multi-beam for one shot is formed by the beam which has passed through the limiting aperture member 206 since beam-on until beam-off is achieved.

The multi-beam which has passed through the limiting aperture member 206 is focused by the objective lens 207, and projected to the substrate 101 with a desired reduction ratio. The deflectors 208, 209 each can deflect the entire multi-beam. The deflection amounts of the deflectors 208, 209 are independently controlled. The irradiation position of the multi-beam on the substrate 101 is controlled by the deflectors 208, 209.

During writing, the XY stage 105 is controlled to be moved at a constant speed continuously. In this process, the irradiation position of the beam is controlled by the deflector 208 so that the irradiation position follows the movement of the XY stage 105. The multi-beams emitted simultaneously are ideally arranged with the pitch which is the product of the arrangement pitch of the multiple openings of the shaping aperture member 203 and the above-mentioned desired reduction ratio. During writing, a raster scan writing operation is performed, in which the multi-beam exposes all pixels defined on the substrate 101 by position control using deflection. When the beam is on pixels including no pattern, the beam is controlled at beam-off by blanking control.

FIG. 3 is a conceptual diagram for explaining a writing operation in the present embodiment. As illustrated in FIG. 3, a writing region 30 on the substrate 101 is virtually divided into e.g., rectangular multiple stripe regions 32 in the y direction (first direction) with a predetermined width, and the longitudinal direction (the x direction or the second direction) of the stripe region 32 perpendicular to the y direction gives the proceed direction of writing. When writing is performed on these stripe regions 32, first, the XY stage 105 is moved to make adjustment so that an irradiation region (beam array) 34 to be irradiated by one-time irradiation with the multi-beam is located at the left end of the first stripe region 32, then writing is started.

When writing is performed on the first stripe region 32, the XY stage 105 is moved in −x direction at a constant speed continuously so that writing is performed on the substrate 101 relatively in +x direction. After completion of writing on the first stripe region 32, the XY stage 105 is stopped. Next, the stage position is moved in −y direction by the stripe width, and the beam array 34 is adjusted to be located at the right end of the second stripe region 32. Subsequently, the XY stage 105 is moved in +x direction at a constant speed continuously so that writing is performed on the substrate 101 in −x direction.

On the third stripe region 32, writing is performed in +x direction, and on the fourth stripe region 32, writing is performed in −x direction. Writing may be performed in the same direction on each stripe region 32, and in this case, an operation of returning the stage position is added after writing, thus the writing time increases.

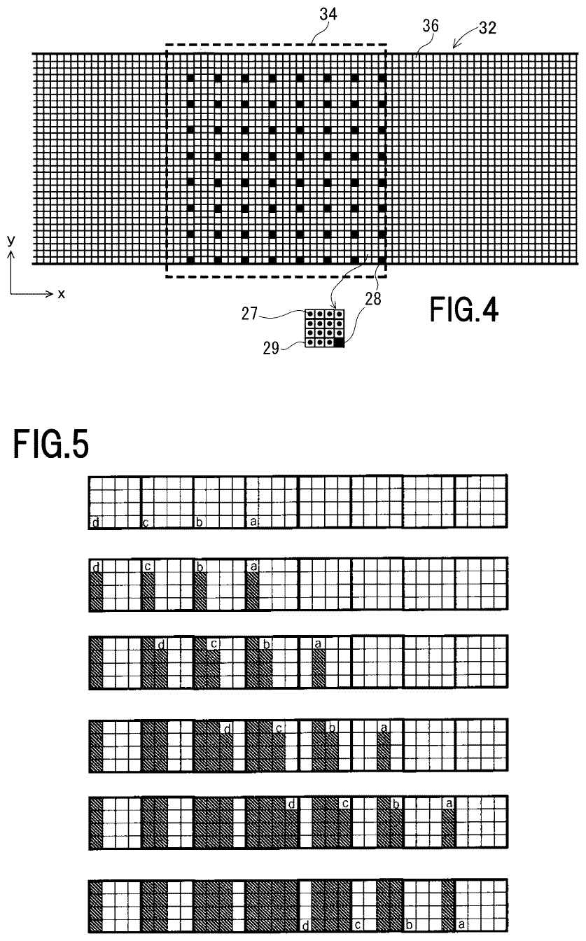

FIG. 4 is a view illustrating an example of an irradiation region of a multi-beam and writing target pixels. In FIG. 4, on the stripe region 32, for example, multiple control grids 27 arranged in a lattice pattern are set on the surface of the substrate 101 with the pitch having the beam size of the multi-beam. For example, approximately 10 nm arrangement pitch is preferable.

The multiple control grids 27 provide ideal irradiation positions (ideal positions) without a positional deviation of multi-beam. The arrangement pitch of the control grids 27 is not limited to the same magnitude as the beam size, and may be any magnitude controllable as the deflection position of the deflector 209. Multiple pixels 36 virtually divided in a mesh shape and each centered at a control grid 27 are set with the same size as the arrangement pitch of the control grids 27.

Each pixel 36 is an irradiation unit region per beam (individual beam) in multi-beam. The example of FIG. 4 illustrates a case where the writing region of the substrate 101 is divided into multiple stripe regions 32 in the y direction with the same width size as the size of the beam array 34 (writing field) able to be irradiated by one-time irradiation with multi-beam 20. The size of the beam array 34 in the x direction is the value obtained by multiplying the beam pitch of multi-beam in the x direction by the number of beams in the x direction. The size of the beam array 34 in the y direction is the value obtained by multiplying the beam pitch of multi-beam in the y direction by the number of beams in the y direction.

FIG. 4 illustrates an example of 8×8 row multi-beam. Note that the multi-beam is not limited to 8×8 rows, and 512×512 row multi-beam may be used as needed. Multiple pixels 28 (writing positions of the beam) able to be irradiated with one-time multi-beam shot are shown as black pixels in the beam array 34. In other words, the pitch between adjacent pixels 28 gives the design pitch between beams in multi-beam. Here, let pitch cell 29 be a region with the size of the beam pitch. In the example of FIG. 4, each pitch cell 29 is formed by 4×4 pixels.

When writing is performed on each stripe region 32, concurrently with the continuous movement of the XY stage 105 in the x direction, the beam position is controlled by the deflectors 208, 209 so that all pixels on the substrate 101 are exposed the same number of times. In this process, the deflector 208 performs deflection control (stage tracking) on the beam position so that the beam during exposure follows the continuous movement of the XY stage 105. The deflector 209 performs control of switching between exposed pixels. When switching is made between exposed pixels, the deflector 209 deflects the beam array in the range of the pitch cell 29.

FIG. 5 illustrates an example in which multi-beam with 4 beams are present in the x direction and arranged with an interval of four times the beam size. Although multi-beam in four rows or a different number of rows may be present in the y direction, since the multi-beam in each row writes a region with a beam pitch width corresponding to the width of a sub-irradiation region 29, it may be understood that FIG. 5 shows the beam arrays in some rows in multi-beam array having multiple rows, and the pixels to be exposed in these.

The example of FIG. 5 shows repetition of the process in which during continuous movement of the stage in −x direction, each beam exposes one row consisting of four pixels in the y direction, then the beam is moved in +x direction to expose another row. As described above, during exposure of four pixels in one row by each beam, concurrently with the stage tracking operation in which the deflector 208 performs continuous deflection to follow the movement of the stage so that the position of the beam array in the x direction on the substrate 101 is fixed, the deflector 209 performs deflection to change the pixels to be exposed in the y direction. After exposure of one row, significant movement of the beam in +x direction is made by the tracking reset operation in which the stage tracking is stopped and the deflection amount of the deflector 208 is returned to the deflection amount at the start of the stage tracking.

In FIG. 5, the group of pixels is partitioned by the region with the beam pitch width, and when the beam moves to another row, the beam moves to a region with another pitch width. This movement is made by controlling the deflection amount to be added in the x direction by the deflector 209. In other words, the raster scan operation is performed by the deflector 208 performing tracking deflection, and the deflector 209 performing deflection within the pitch cell 29. Note that, in the exposure process illustrated in FIG. 5, in up to the third region with the pitch width from the left, only part of the pixels is exposed, and in the regions with the pitch width on the further right, all pixels are exposed by further repeating the process. In other words, immediately after the start of exposure, those three beam pitch regions are incompletely exposed, thus the writing operation is started from a region on the left of the writing region so that the actual writing region does not include the incompletely exposed regions.

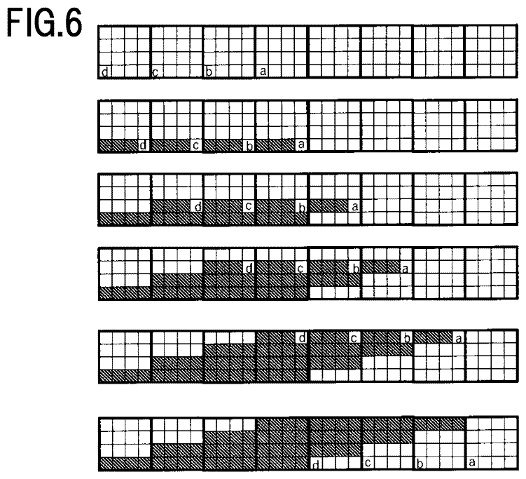

In this example, during a tracking period, multiple pixels are exposed sequentially in +y direction, however, the invention is not limited to this. For example, as illustrated in FIG. 6, the exposure can be performed in +x direction sequentially.

In the multi-beam writing, in order to average the error in position and current amount for each beam, multiple-writing is preferably performed with a necessary irradiation amount divided into multiple processes of writing (exposures).

“Within-stripe multiple-writing” is known in which the beam array is divided into multiple regions with a predetermined same width in the x direction (the proceed direction of writing), and during writing of one stripe region, the beam of each divided region writes the same area.

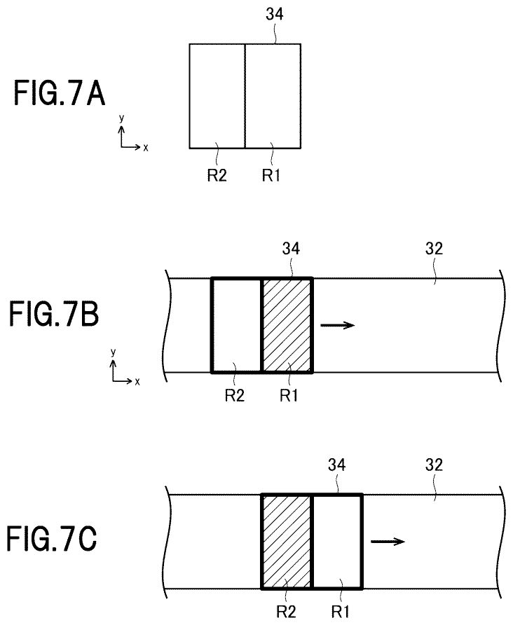

For example, when a shot order assigned to the pixels in each beam pitch region is repeated twice, as illustrated in FIG. 7A(a), the beam array 34 is divided into two regions (sub-beam array), a block region R1 and a block region R2, and the pixels in the stripe 32 are each written once by the beam belonging to the region R1, and the beam belonging to the region R2. As illustrated in FIGS. 7B, 7C, the shaded region in FIGS. 7B, 7C is irradiated with the beam of the region R1, then irradiated with the beam of the region R2. Therefore, one region is written twice, so the multiplicity is two.

For example, in FIGS. 5 and 6, 4×4 pixels in beam pitch region are exposed once by one of multi-beam with 4 beams a, b, c, d, particularly, 4×4 pixels are each exposed once by the right half a, b of multi-beam with 4 beams in one row. Subsequently, 4×4 pixels are each exposed once by the left half c, d of multi-beam. In FIGS. 5 and 6, each of the multi-beam with 4 beams a, b, c, d performs writing with a multiplicity of one by exposing four pixels out of 4×4 pixels in beam pitch region; however, when the multi-beam with 4 beams a, b, c, d are divided into two block regions, specifically, multi-beam a, b and multi-beam c, d, then writing with a multiplicity of two is performed, each of the multi-beam with 4 beams a, b, c, d exposes eight pixels out of 4×4 pixels in beam pitch region.

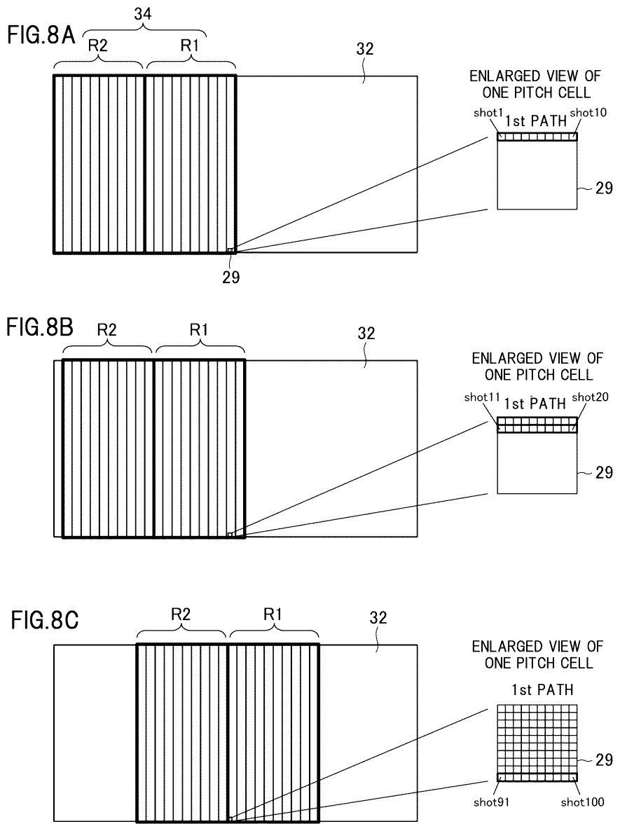

A specific example of a writing method by the within-stripe multiple-writing will be described. For example, as illustrated in FIG. 8A, the beam array 34 is divided into two block regions R1, R2. It is assumed that each side of the beam array is 80 μm, and the width of the stripe region 32 is also 80 μm. The pitch cell 29 obtained by dividing the stripe region by the inter-beam pitch size of multi-beam is assumed to have each side of 160 nm. The shot size (size of individual beam) is assumed to be 16 nm. The pitch cell consists of 10 pixels×10 pixels=100 pixels.

In FIG. 8, with a focus on the pitch cell 29 which is one of the pitch cells, how the 10×10 pixels in the pitch cell 29 are exposed by the beam array 34 will be described. Multiple tracking start positions are set in the stripe 32. The position of the right end of the pitch cell in which the beam of the right end of the beam array is located in the stripe 32 at the start of tracking, is indicated by a vertical line of FIG. 8. One or more pitch cells are included between a tracking start position and the subsequent start position. In the example of FIG. 8, multiple pitch cells are included.

Note that at this point, the inter-beam pitch size does not mean the pitch size between adjacently disposed beams as hardware, but mean between the beams in the multi-beam used for writing. For example, when the beams defined as hardware are alternately used (OFF for other than those beams) to limit the total amount of current, the inter-beam pitch size is twice the pitch defined as hardware.

10 pixels in the first row of the pitch cell are sequentially exposed using one beam for the block region R1 while the XY stage 105 is being moved continuously, and the stage tracking is being performed. When shot is performed 10 times (shot 1 to shot 10), the tracking reset, specifically, the operation of returning the beam position in a deflection coordinate system to the tracking start position is performed. In this operation, the beam position on the substrate 101 is moved to a pitch cell on the right of the pitch cell at the time of tracking reset. In other words, on the substrate 101, the beam position is moved in +x direction, and positioned in another pitch cell. Since the multi-beam is collectively deflected by the deflector 208, the beams in the multi-beam are moved to the pitch cell on the right by the tracking reset with the same amount of movement and the same number of beams.

As illustrated in FIG. 8B, the next stage tracking is started, and 10 pixels in the second row of the pitch cell are sequentially exposed using another beam for the block region R1. After shot is performed 10 times, specifically, shot 11 to shot 20 are performed, tracking reset is made.

In this manner, for one-time stage tracking, the writing operation including the exposure of 10 pixels and the tracking reset is repeatedly performed, thus as illustrated in FIG. 8C, 100 pixels in the pitch cell 29 of interest are each exposed once by multiple beams for the block region R1. Specifically, while the block region R1 is passing through the pitch cell 29 of interest, 100 pixels in the pitch cell 29 are each exposed once, and exposure of multiplicity of one (first of multiple exposures) by multi-beam in the block region R1 is completed. The shot order of 100 pixels is as illustrated in FIG. 22.

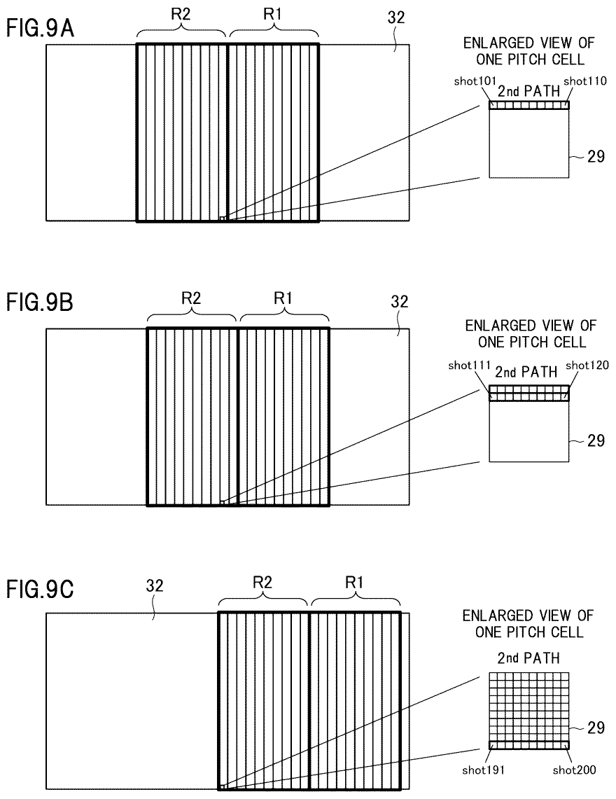

The writing operation is further continued, and the pitch cell 29 of interest is exposed by the beams for the block region R2. Due to tracking reset after completion of the exposure by the beams for the block region R1 with a multiplicity of one, the beams for the region R2 are located in the pitch cell 29 of interest. Thus, as illustrated in FIG. 9A, 10 pixels in the first row are sequentially exposed using one beam for the block region R2. After shot is performed 10 times, specifically, shot 101 to shot 110 are performed, tracking reset is made. The second-time (the second pass) exposure is performed on 10 pixels in the first row.

As illustrated in FIG. 9B, the next stage tracking is started, and 10 pixels in the second row of the pitch cell are sequentially exposed using another beam for the block region R2. After shot is performed 10 times, specifically, shot 111 to shot 120 are performed, tracking reset is made.

The exposure of 10 pixels and the tracking reset are repeatedly made while performing stage tracking, and as illustrated in FIG. 9C, 100 pixels in the pitch cell are each exposed once by multiple beams for the block region R2. Specifically, while the block region R2 is passing through the pitch cell 29 of interest, 100 pixels in the pitch cell 29 are each exposed once, and exposure of multiplicity of one (second of multiple exposures) by multi-beam in the block region R2 is completed.

100 pixels in the pitch cell are each exposed twice by the writing process, thus the multiplicity is two.

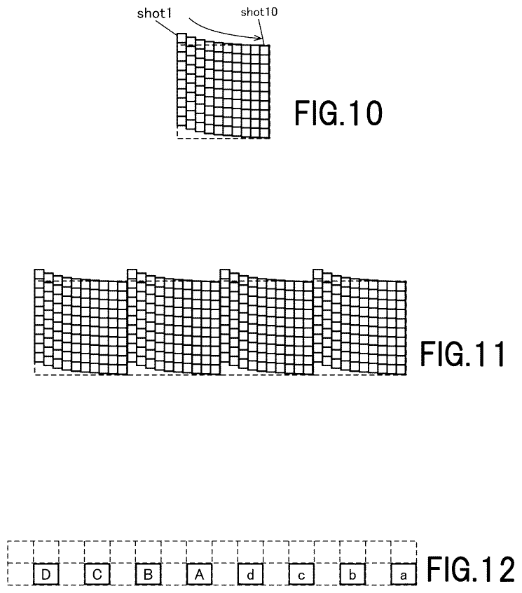

In the example illustrated in FIGS. 8A to 8C, FIGS. 9A to 9C, the pixels in the first row of one pitch cell are shot from the left to the right, then the pixels in the second row are shot from the left to the right, thus a monotonous shot order is applied. When beam drift occurs immediately after the tracking reset, a deviation of the shot position as illustrated in FIG. 10 occurs. Specifically, when due to the tracking reset operation, a charge is generated in the column to cause a positional deviation of the beam, and the positional deviation decays during exposure operations for 10 pixels during tracking, a distribution of the deviation of the shot position as in FIG. 10 is generated.

In the example above, each pitch cell is shot in the same shot order in the first and second of multiple exposures, thus as illustrated in FIG. 11, a systematic error occurs in the shot position of each pixel, which causes an error in the position and the linewidth of a writing pattern.

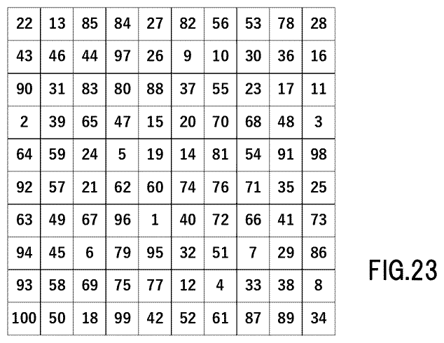

The systematic error can be made unlikely to occur by positionally changing the shot order within each beam pitch cell. For example, the distribution of error in shot position can be spatially dispersed when a shot order is used which allows the exposure positions in the beam pitch cell during tracking to be dispersed without deviating in neither the x direction nor the y direction as illustrated in FIG. 23. Hereinafter such a shot order is referred to as a random shot order. A random shot order can be generated by a random number generator. In the multi-beam writing, the positions of the multi-beam are collectively controlled by the deflector 209, thus the pitch cells simultaneously exposed are shot in the same shot order, and a systematic error according to the shot order may occur, which prevents the improvement of the writing accuracy.

The inventors have found that in the within-stripe multiple-writing system, the writing accuracy can be improved by assigning different shot orders to multiple pitch cells in the stripe region, and averaging the systematic error due to shot order.

An example of such a writing method will be described with reference to FIG. 12 to FIGS. 14A to 14D. For illustration purpose, as illustrated in FIG. 12, within-stripe multiple-writing with a multiplicity of two is performed using a beam array consisting of 8×1 individual beams (beamlets). It is assumed that each pitch cell consists of 2 pixels×2 pixels=4 pixels.

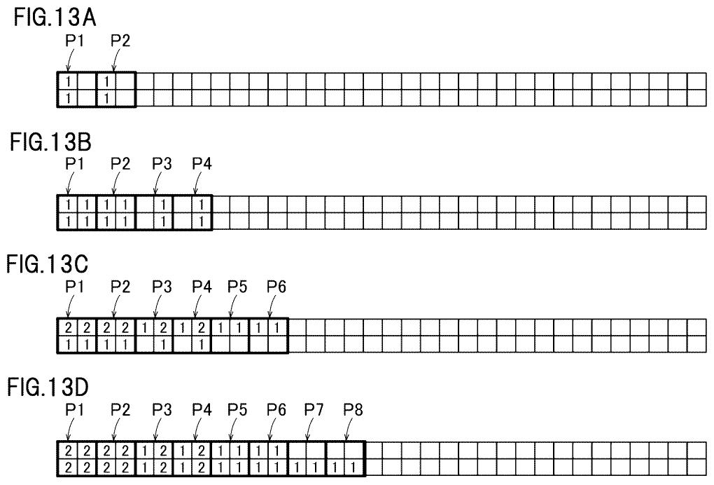

First, as illustrated in FIG. 13A, while stage tracking is performed, the beam array is moved in the y direction, and two left pixels in relevant pitch cells are shot. FIG. 13A illustrates a state in which individual beams a, b shot two left pixels in pitch cells P2, P1. The numeral in each pixel indicates the number of shots to the pixel.

The tracking reset is made, and the writing position of the beam is adjusted to the lower right pixel of each pitch cell. As illustrated in FIG. 13B, while stage tracking is performed, the beam array is moved in the y direction, and two right pixels in relevant pitch cells are shot.

FIG. 13B illustrates a state in which individual beams a, b shot two right pixels in pitch cells P4, P3, and individual beams c, d shot two right pixels in pitch cells P2, P1.

The tracking reset is made, and the writing position of the beam is adjusted to the upper left pixel of each pitch cell. As illustrated in FIG. 13C, while stage tracking is performed, the beam array is moved in the x direction, and two upper pixels in relevant pitch cells are shot.

FIG. 13C illustrates a state in which individual beams a, b shot two upper pixels in pitch cells P6, P5, individual beams c, d shot two upper pixels in pitch cells P4, P3, and individual beams A, B shot two upper pixels in pitch cells P2, P1.

The tracking reset is made, and the writing position of the beam is adjusted to the lower left pixel of each pitch cell. As illustrated in FIG. 13D, while stage tracking is performed, the beam array is moved in the x direction, and two lower pixels in relevant pitch cells are shot.

FIG. 13D illustrates a state in which individual beams a, b shot two lower pixels in pitch cells P8, P7, individual beams c, d shot two lower pixels in pitch cells P6, P5, individual beams A, B shot two lower pixels in pitch cells P4, P3, and individual beams C, D shot two lower pixels in pitch cells P2, P1.

Thus, in pitch cells P1, P2, four pixels are each exposed twice.

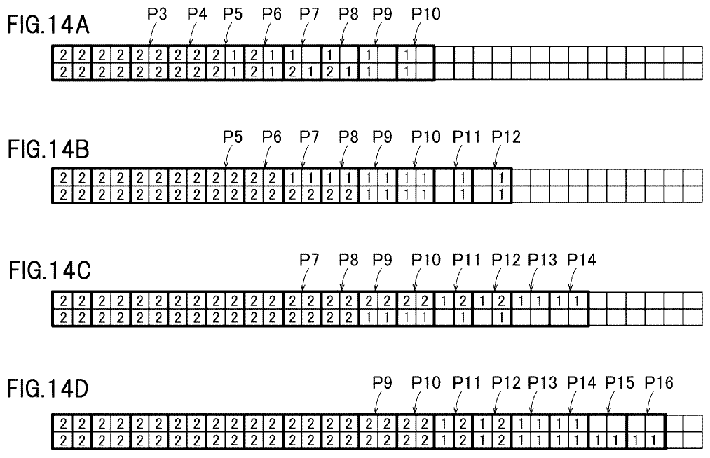

The tracking reset is made, and the writing position of the beam is adjusted to the lower left pixel of each pitch cell. As illustrated in FIG. 14A, while stage tracking is performed, the beam array is moved in the y direction, and two left pixels in relevant pitch cells are shot.

FIG. 14A illustrates a state in which individual beams a, b shot two left pixels in pitch cells P10, P9, individual beams c, d shot two left pixels in pitch cells P8, P7, individual beams A, B shot two left pixels in pitch cells P6, P5, and individual beams C, D shot two left pixels in pitch cells P4, P3.

Thus, in pitch cells P3, P4, four pixels are each exposed twice.

The tracking reset is made, and the writing position of the beam is adjusted to the lower right pixel of each pitch cell. As illustrated in FIG. 14B, while stage tracking is performed, the beam array is moved in the y direction, and two right pixels in relevant pitch cells are shot.

FIG. 14B illustrates a state in which individual beams a, b shot two right pixels in pitch cells P12, P11, individual beams c, d shot two right pixels in pitch cells P10, P9, individual beams A, B shot two right pixels in pitch cells P8, P7, and individual beams C, D shot two right pixels in pitch cells P6, P5.

Thus, in pitch cells P5, P6, four pixels are each exposed twice.

The tracking reset is made, and the writing position of the beam is adjusted to the upper left pixel of each pitch cell. As illustrated in FIG. 14C, while stage tracking is performed, the beam array is moved in the x direction, and two upper pixels in relevant pitch cells are shot.

FIG. 14C illustrates a state in which individual beams a, b shot two upper pixels in pitch cells P14, P13, individual beams c, d shot two upper pixels in pitch cells P12, P11, individual beams A, B shot two upper pixels in pitch cells P10, P9, and individual beams C, D shot two upper pixels in pitch cells P8, P7.

Thus, in pitch cells P7, P8, four pixels are each exposed twice.

The tracking reset is made, and the writing position of the beam is adjusted to the lower left pixel of each pitch cell. As illustrated in FIG. 14D, while stage tracking is performed, the beam array is moved in the x direction, and two lower pixels in relevant pitch cells are shot.

FIG. 14D illustrates a state in which individual beams a, b shot two lower pixels in pitch cells P16, P15, individual beams c, d shot two lower pixels in pitch cells P14, P13, individual beams A, B shot two lower pixels in pitch cells P12, P11, and individual beams C, D shot two lower pixels in pitch cells P10, P9.

Thus, in pitch cells P9, P10, four pixels are each exposed twice.

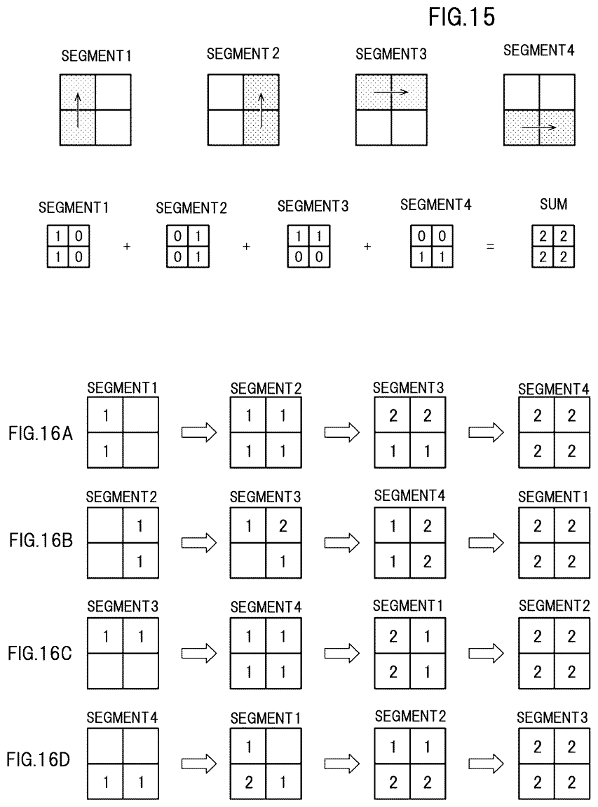

When the number of tracking times required for irradiation of one pitch cell is M (M is an integer greater than 1), M segments are prepared which define a shot order for multiple different pixels within a pitch cell, and stored in the storage 140. Each segment defines the pixels to be shot and the shot order in a pitch cell during one-time tracking. In the example illustrated in FIGS. 13A to 13D, FIG. 14A to 14D, the number of tracking times required for irradiation of one pitch cell is four, and four segments 1 to 4 as illustrated in FIG. 15 are prepared, then writing is performed by repeatedly assigning a different segment to the shot order for each tracking.

When a segment is regarded as a two-dimensional matrix having an element of 1 for a pixel assigned a shot and an element of 0 for other pixels, each element of the sum of matrices corresponding to the segments 1 to 4 matches the within-stripe multiplicity.

Four pixels in pitch cells P1, P2 are exposed in the order as illustrated in FIG. 16A. Specifically, writing based on segment 1, writing based on segment 2, writing based on segment 3, and writing based on segment 4 are sequentially performed.

Four pixels in pitch cells P3, P4 are exposed in the order as illustrated in FIG. 16B. Specifically, writing based on segment 2, writing based on segment 3, writing based on segment 4, and writing based on segment 1 are sequentially performed.

Four pixels in pitch cells P5, P6 are exposed in the order as illustrated in FIG. 16C. Specifically, writing based on segment 3, writing based on segment 4, writing based on segment 1, and writing based on segment 2 are sequentially performed.

Four pixels in pitch cells P7, P8 are exposed in the order as illustrated in FIG. 16D. Specifically, writing based on segment 4, writing based on segment 1, writing based on segment 2, and writing based on segment 3 are sequentially performed.

In this manner, different shot orders are assigned to multiple pitch cells in the stripe region by applying a different segment for each tracking, thus a systematic error due to shot order can be reduced.

When such a writing process is performed, the area ratio calculator 111 reads writing data from the storage 140, and for each pixel 36, calculates a pattern area density ρ(x) in the pixel 36 to generate an area ratio map. The process is performed for each stripe region 32, for example.

In addition, the area ratio calculator 111 virtually divides a writing region (e.g., a stripe region 32) into multiple proximal mesh regions (mesh regions for proximity effect correction calculation) in a mesh shape with a predetermined size. The size of the proximal mesh regions is preferably set to approximately 1/10 the extent of influence of the proximity effect, e.g., approximately 1 μm. The area ratio calculator 111 reads writing data from the storage 140, and for each proximal mesh region, calculates a pattern area density ρ′ of a pattern to be disposed in the proximal mesh region.

Subsequently, for each proximal mesh region, the area ratio calculator 111 calculates a proximity effect correction coefficient Dp(x) (corrected irradiation amount) to correct the proximity effect. Unknown proximity effect correction coefficient Dp(x) can be defined by a threshold model for proximity effect correction, same as in a conventional technique, the threshold model using a backscattering coefficient η, an irradiation amount threshold Dth of the threshold model, the pattern area density ρ′, and distribution function g(x).

For each pixel 36, the irradiation amount calculator 117 calculates an incident irradiation amount D(x) (dose amount, exposure amount) for irradiating the pixel 36. The incident irradiation amount D(x) may be calculated as the value obtained by, for example, multiplying a predetermined reference irradiation amount Dbase by the pattern area density ρ(x) and the proximity effect correction coefficient Dp(x). The reference irradiation amount Dbase can be defined by Dth/(½+η), for example.

For each shot, the irradiation amount calculator 117 calculates the irradiation amount of each beam (individual beam) in multi-beam. For example, the irradiation amount calculator 117 calculates the irradiation amount per pass by dividing the incident irradiation amount D(x) of the pixel irradiated with an individual beam by the multiplicity.

The writing controller 118 converts the irradiation amount of each beam calculated by the irradiation amount calculator 117 into irradiation time data, and transfers the irradiation time data to the deflection control circuit 130. The deflection control circuit 130 controls the ON/OFF of each blanker of the blanking aperture array substrate 204 based on the irradiation time data. In addition, the deflection control circuit 130 controls the deflection amount of the deflectors 208, 209 to achieve the shot order as illustrated in FIGS. 13A to 13D, FIG. 14A to 14D.

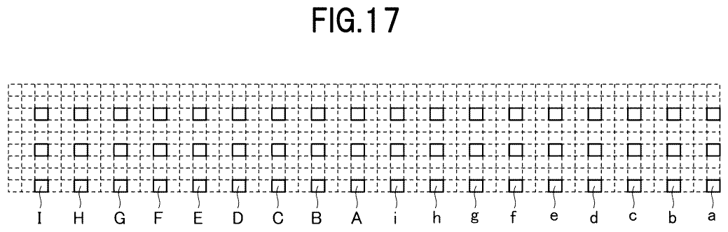

In the within-stripe multiple-writing system, as another example of a writing method for assigning different shot orders to multiple pitch cells in the stripe region, a case where the pitch cell has a larger number of pixels will be described with reference to FIG. 17 to FIGS. 20A to 20C.

As illustrated in FIG. 17, within-stripe multiple-writing with a multiplicity of two is performed using a beam array consisting of 3×18 individual beams (beamlets). Each pitch cell consists of 3 pixels×3 pixels=9 pixels.

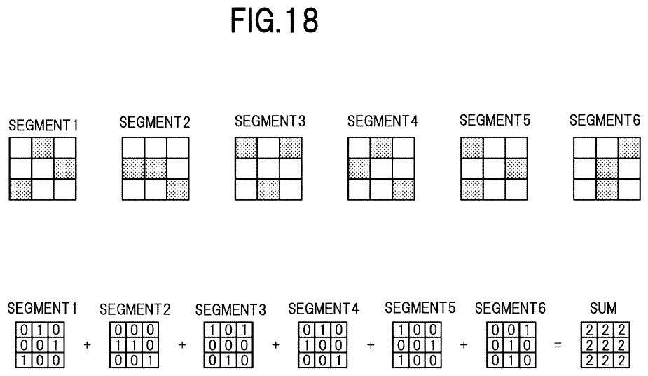

It is assumed that the number of tracking times required for irradiation of one pitch cell is six. Segment 1 to segment 6 as illustrated in FIG. 18 are prepared in advance, and stored in the storage 140. When a segment is regarded as a two-dimensional matrix having an element of 1 for a pixel assigned a shot and an element of 0 for other pixels, the value of each element of the sum of segments 1 to 6 is two (within-stripe multiplicity).

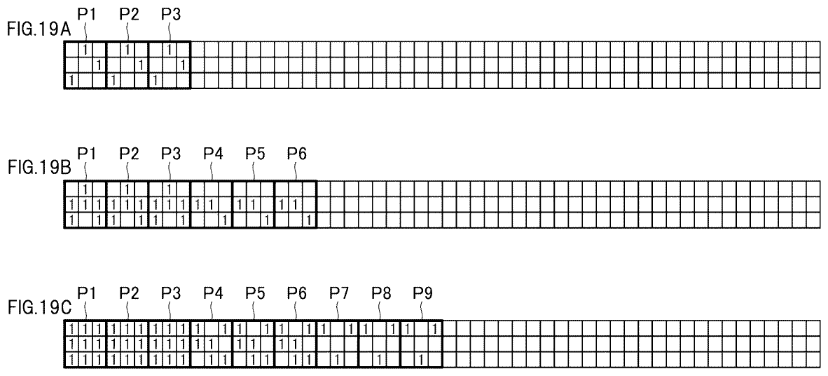

First, as illustrated in FIG. 19A, while stage tracking is performed, three pixels in relevant pitch cells are shot in the shot order defined by segment 1. FIG. 19A illustrates a state in which individual beams a, b, c shot three pixels in pitch cells P3, P2, P1. After three pixels are shot, the tracking reset is made.

The stage tracking is restarted, and as illustrated in FIG. 19B, three pixels in relevant pitch cells are shot in the shot order defined by segment 2. FIG. 19B illustrates a state in which individual beams a to f shot three pixels in pitch cells P6 to P1. After three pixels are shot, the tracking reset is made.

The stage tracking is restarted, and as illustrated in FIG. 19C, three pixels in relevant pitch cells are shot in the shot order defined by segment 3. FIG. 19C illustrates a state in which individual beams a to i shot three pixels in pitch cells P9 to P1. After three pixels are shot, the tracking reset is made.

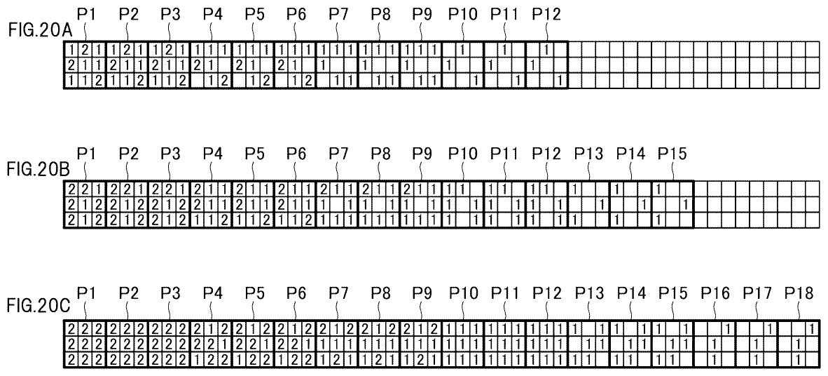

The stage tracking is restarted, and as illustrated in FIG. 20A, three pixels in relevant pitch cells are shot in the shot order defined by segment 4. FIG. 20A illustrates a state in which individual beams a to i and individual beams A to C shot three pixels in pitch cells P12 to P1. After three pixels are shot, the tracking reset is made.

The stage tracking is restarted, and as illustrated in FIG. 20B, three pixels in relevant pitch cells are shot in the shot order defined by segment 5. FIG. 20B illustrates a state in which individual beams a to i and individual beams A to F shot three pixels in pitch cells P15 to P1. After three pixels are shot, the tracking reset is made.

The stage tracking is restarted, and as illustrated in FIG. 20C, three pixels in relevant pitch cells are shot in the shot order defined by segment 6. FIG. 20C illustrates a state in which individual beams a to i and individual beams A to I shot three pixels in pitch cells P18 to P1.

Thus, in pitch cells P1 to P3, nine pixels are each exposed twice. This example shows a complicated shot order in which each segment includes both deflection in the x direction and deflection in the y direction, and the effect of reducing the systematic error by multiple-writing can be further improved.

When systematic drift occurs depending on a deflected shot direction, it is preferable to prepare a segment in which the shot order is reversed. For example, deflector drift is known in which when the beam is deflected in +x direction, the shot position drifts from a design position in −x direction, and when the beam is deflected in −x direction, the shot position drifts from a design position in +x direction.

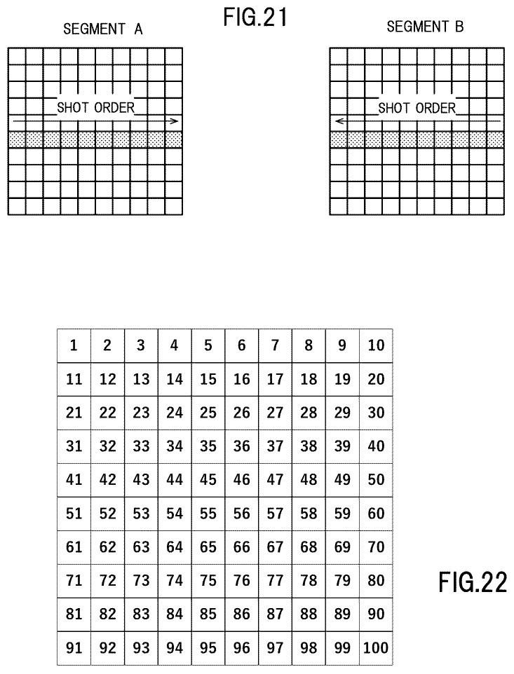

In this case, as illustrated in FIG. 21, using a segment having the same pixels to be shot and a reversed shot order, error can be cancelled, and the positional accuracy of a writing pattern can be further improved.

As illustrated in FIG. 18, when the segments same in number as the number M of tracking times required for irradiation of one pitch cell are regarded as a two-dimensional matrix having an element of 1 for a pixel assigned a shot and an element of 0 for other pixels, each element of the sum of the M segments should match the within-stripe multiplicity. As long as this constraint is satisfied, no other constraint is applied to the shot order, and the shot order may be random using a random number.

In the embodiment above, different segments may be used for each stripe region. For example, in the example illustrated in FIG. 17 to FIGS. 20A to 20C, segments 1 to 6 are used for writing of the first stripe region. For writing of the second stripe region, segments 7 to 12 different from segments 1 to 6 are used. Using different segments for each stripe region, reduction in systematic error due to shot order can be achieved not only in the x direction, but also in the y direction.

The reduction in systematic error due to shot order in the y direction can also be achieved by changing the order of application of segments for each stripe region. For example, in the example illustrated in FIG. 17 to FIGS. 20A to 20C, in the first stripe region, writing is repeatedly performed in the order of segment 1, segment 2, segment 3, segment 4, segment 5, and segment 6. In the second stripe region, writing is repeatedly performed in the order of segment 2, segment 4, segment 5, segment 1, segment 6, and segment 3. In the third stripe region, writing is repeatedly performed in the order of segment 5, segment 1, segment 6, segment 3, segment 2, and segment 4.

In the embodiment above, an example has been illustrated in which there is a one-to-one correspondence between the timing of switching the beam for irradiating beam pitch cell and the timing of tracking reset; however, the invention is not limited to this configuration. For example, the tracking reset may be made between shots when an individual beam shots each pixel in a beam pitch cell. In other words, the tracking reset may be made for each shot. In that case, the region where a segment is generated is the cell defined as a largest region irradiated with one individual beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. In the embodiment, within-stripe multiple-writing with a multiplicity of two has been described. However, the multiplicity is not limited to two, but can be four or eight, etc. The above embodiment describes a multi-charged particle beam apparatus in which the charged-particle beam is controlled by a blanking aperture array. The embodiment is also applicable to a multi-charged particle beam apparatus without a blanking aperture array or a multi-laser beam writing apparatus using digital micromirror devices (DMDs). The accompanying claims and their equivalents are intended to cover such forms or modifications as would fall within the scope and spirit of the inventions.

What is claimed is:

1. A multi-beam writing method for dividing a writing region of a substrate on a stage to be irradiated with a beam array of a multi-beam into multiple stripe regions with a predetermined width in a direction perpendicular to a proceed direction of writing, dividing each of the stripe regions into multiple pixels each of which is an irradiation unit region for each of individual beams included in the multi-beam, and writing each stripe region with a predetermined within-stripe multiplicity of N, where N is an integer greater than 1, the multi-beam writing method comprising:
generating M different types of segments that define a shot order for multiple pixels belonging to each of multiple cells into which the stripe region is divided, the M being an integer greater than 1;
irradiating the multiple pixels in the cell with a first individual beam using (m−1)th segment, where m is an integer such that 2≤m≤M, while the multi-beam is being deflected, then irradiating the multiple pixels in the cell with a second individual beam different from the first individual beam using mth segment; and
writing all pixels in each cell with the multiplicity of N by repeating irradiation sequentially using the M types of segments.

2. The multi-beam writing method according to claim 1,
wherein the cell is a pitch cell obtained by dividing the stripe region by an inter-beam pitch size of the multi-beam used for writing, and
while tracking is performed by deflecting the multi-beam so as to follow movement of the stage, multiple pixels in the pitch cell are irradiated with the first individual beam using the (m−1)th segment, and after the tracking reset, the multiple pixels in the pitch cell are irradiated with the second individual beam using the mth segment.

3. The multi-beam writing method according to claim 1,
wherein the cell is a cell obtained by dividing the stripe region by a largest region irradiated with one individual beam in the multi-beam.

4. The multi-beam writing method according to claim 1,
wherein when the M types of segments are each regarded as a two-dimensional matrix having an element of 1 for a pixel assigned a shot and an element of 0 for a pixel not assigned a shot, a value of each element of a sum of two-dimensional matrices corresponding to the M types of segments matches the predetermined multiplicity.

5. The multi-beam writing method according to claim 1,
wherein two segments of the M types of segments have same pixels to be shot, and reversed shot orders.

6. The multi-beam writing method according to claim 1,
wherein the M types of segments used for writing a first stripe region are different from the M types of segments used for writing a second stripe region.

7. A multi-beam writing apparatus comprising:
a movable stage on which a substrate as a writing target is placed;
a multi-beam former configured to form a multi-beam;
a storage storing writing data, and M different types of segments that are generated to define a shot order for multiple pixels belonging to each of multiple cells included in each of multiple stripe regions into which a writing region of the substrate is divided by a predetermined width in a direction perpendicular to a proceed direction of writing, the M being an integer greater than 1; and
a writing controller configured to control writing using the writing data and the segments,
wherein the multiple pixels are each an irradiation unit region for each of individual beams included in the multi-beam, and
the writing controller irradiates the multiple pixels in the cell with a first individual beam in the multi-beam using (m−1)th segment, where m is an integer such that 2≤m≤M, while deflecting the multi-beam, then irradiates the multiple pixels in the cell with a second individual beam different from the first individual beam using mth segment, and controls to write each of the multiple stripe regions with a predetermined within-stripe multiplicity of N, where N is an integer greater than 1.
